(19) United States
(12) Patent Application Publication
(10) Pub. No.: US 2026/0369475 A1
(43) Pub. Date: Nov. 19, 2026

(54) CAPACITOR COMPONENT, METHOD FOR MANUFACTURING SAME, AND INTEGRATED CIRCUIT CHIP PACKAGE HAVING CAPACITOR COMPONENT

(71) Applicant: POINT ENGINEERING CO., LTD., Asan-si (KR)

(72) Inventors: Bum Mo AHN, Suwon-Si (KR); Seung Ho PARK, Hwaseong-Si (KR); Sung Hyun BYUN, Suwon-Si (KR)

(73) Assignee: POINT ENGINEERING CO., LTD., Asan-si (KR)

(21) Appl. No.: 19/137,286

(22) PCT Filed: Dec. 5, 2023
(86) PCT No.: PCT/KR2023/095101

§ 371 Date: Jun. 9, 2025

(30) Foreign Application Priority Data
Dec. 9, 2022 (KR) 10-2022-0171777

(51) Int. Cl. H01G 4/01

(52) U.S. Cl. CPC H01G 4/01

(57) ABSTRACT

The present invention provides a miniaturizable capacitor component suitable for high-frequency environments, comprising an anodized membrane body with a plurality of pores, a first wire metal layer on inner walls of the pores, a dielectric layer on the first wire metal layer, a second wire metal layer on the dielectric layer, and a lower common electrode layer connected to the first wire metal layer, and further provides a method for manufacturing the same and an integrated circuit chip package including the capacitor component.

### CROSS-REFERENCE TO RELATED APPLICATION

This application is a 371 of international application of PCT application serial no. PCT/KR2023/095101, filed on Dec. 5, 2023, which claims the priority benefit of Korea application no. 10-2022-0171777, filed on Dec. 9, 2022. The entirety of each of the above mentioned patent applications is hereby incorporated by reference herein and made a part of this specification.

### TECHNICAL FIELD

The present invention relates to a capacitor component, a method of manufacturing the same, and an integrated circuit chip package comprising the same.

### BACKGROUND

A capacitor plays a role in stabilizing the flow of electricity within a circuit by collecting and discharging electricity in the circuits of information communication devices and various electronic products. The stable supply of energy in various electronic products, such as information communication devices, has become an important factor. Generally, this function is performed by a capacitor.

Capacitors are classified into various types depending on the dielectric material, among which MLCC (Multilayer Ceramic Capacitor) is currently the most widely used in the electronics industry. This is because it is easy to implement a smaller form factor compared to conventional capacitors.

However, it is practically impossible to reduce the size of MLCC, which is the mainstream in the current capacitor market, to below 0.2 mm (200 μm). Although MLCC is a promising technology expected to continue expanding its market size, it has reached its limit in meeting the needs of customers who demand smaller capacitors with superior electrical characteristics.

In particular, MLCC has a multilayer structure, which poses a problem in that it is difficult for current to flow in and out quickly in high-frequency environments. Therefore, the development of capacitors suitable for high-frequency environments is urgently needed.

### PRIOR ARTS DOCUMENTS

### Patent Documents

(Patent Document 1) Registration Number 10-2192426, Registered Patent Gazette

(Patent Document 2) Registration Number 10-2189805, Registered Patent Gazette

### SUMMARY

### Technical Problem

Accordingly, the present invention has been devised to solve the problems of the prior art described above, and the purpose of the present invention is to provide a capacitor component suitable for a high-frequency environment and capable of miniaturization, a method of manufacturing the same, and an integrated circuit chip package comprising the same.

### MEANS FOR SOLVING THE PROBLEM

To achieve the above-described objectives, a capacitor component according to the present invention comprises: an anodized membrane body having a plurality of pores; a first wire metal layer provided on an inner wall of the pores; a dielectric layer provided on the first wire metal layer; a second wire metal layer provided on the dielectric layer; and a lower common electrode layer connected to the first wire metal layer at a lower portion of the anodized membrane body.

In addition, an end of the first wire metal layer protrudes from the lower portion of the anodized membrane body and is embedded in the lower common electrode layer.

Meanwhile, a capacitor component according to the present invention comprises: a lower common electrode layer; an anodized membrane body provided on an upper portion of the common electrode layer and having a plurality of pores; and a capacitor wire including a capacitor structure formed inside the pores, wherein an end of the capacitor wire is connected to the lower common electrode layer.

In addition, the capacitor wire comprises: a first wire metal layer provided on an inner wall of the pores; a dielectric layer provided on the first wire metal layer; and a second wire metal layer provided on the dielectric layer.

In addition, an end of the capacitor wire protrudes from a lower portion of the anodized membrane body and is embedded in the lower common electrode layer.

In addition, the capacitor wire comprises: a surface portion provided on a surface of the anodized membrane body; a column portion provided on an inner wall of the pores; and a bottom portion continuously formed with the column portion and protruding from the lower portion of the anodized membrane body to be embedded in the lower common electrode layer.

In addition, the lower common electrode layer is provided to extend in a horizontal direction, and the capacitor wire extends in a vertical direction and a plurality thereof are provided spaced apart in the horizontal direction.

Meanwhile, a capacitor component according to the present invention comprises: an anodized membrane body provided on an upper portion of the lower common electrode layer and having a plurality of pores; a capacitor wire including a capacitor structure formed in at least some of the pores; and a functional wire including a functional structure formed in at least some of the pores, wherein an end of the capacitor wire is connected to the lower common electrode layer.

In addition, the functional structure is a metal material.

In addition, the functional structure is an insulating material.

In addition, an end of the functional wire is closed by a patternable material.

Meanwhile, a capacitor component according to the present invention comprises: an upper common electrode layer; a lower common electrode layer; an anodized membrane body provided between the upper common electrode layer and the lower common electrode layer and having a plurality of pores; and a capacitor wire including a capacitor structure formed inside the pores, wherein an end of the capacitor wire is connected to the lower common electrode layer.

In addition, the capacitor wire comprises: a first wire metal layer provided on an inner wall of the pores; a dielectric layer provided on the first wire metal layer; and a second wire metal layer provided on the dielectric layer, wherein the upper metal layer is provided on an upper portion of the second wire metal layer.

Meanwhile, an integrated circuit chip package according to the present invention comprises: a package substrate; a semiconductor chip mounted on the package substrate; a molding portion protecting the semiconductor chip; and a capacitor component provided inside or on the package substrate, wherein the capacitor component comprises: a lower common electrode layer; an anodized membrane body provided on an upper portion of the lower common electrode layer and having a plurality of pores; and a capacitor wire including a capacitor structure formed inside the pores, wherein an end of the capacitor wire is connected to the lower common electrode layer.

Meanwhile, a method of manufacturing a capacitor component according to the present invention comprises: preparing an anodized membrane body; forming a capacitor wire by filling a capacitor structure in pores of the anodized membrane body; forming an upper common electrode layer on an upper portion of the capacitor wire; and removing a portion of the anodized membrane body and forming a lower common electrode layer such that a portion of an end of the capacitor wire is embedded.

### Effect of the Invention

The present invention provides a capacitor component suitable for a high-frequency environment and capable of miniaturization, a method of manufacturing the same, and an integrated circuit chip package comprising the same.

### BRIEF DESCRIPTION OF DRAWINGS

FIG. 1 is a cross-sectional view of a capacitor component according to a preferred first embodiment of the present invention.

FIG. 2 is a cross-sectional view of a capacitor wire according to a preferred first embodiment of the present invention.

FIG. 3 is an enlarged view of portion A of FIG. 1.

FIGS. 4A to 9B are diagrams for explaining a method of manufacturing a capacitor component according to a preferred first embodiment of the present invention.

FIG. 10 is a cross-sectional view of a capacitor component according to a preferred second embodiment of the present invention.

FIGS. 11A to 15 are diagrams for explaining a method of manufacturing a capacitor component according to a preferred second embodiment of the present invention.

FIG. 16 is a cross-sectional view of a capacitor component according to a preferred third embodiment of the present invention.

FIGS. 17A to 21 are diagrams for explaining a method of manufacturing a capacitor component according to a preferred third embodiment of the present invention.

FIG. 22 is a cross-sectional view of an integrated circuit chip package with an embedded capacitor component according to a preferred embodiment of the present invention.

### DETAILED DESCRIPTION OF THE EMBODIMENTS

The following content merely illustrates the principles of the invention. Therefore, a person skilled in the art can implement the principles of the invention and invent various devices included in the concept and scope of the invention, even if they are not explicitly described or shown in this specification. Furthermore, all conditional terms and embodiments listed in this specification are, in principle, explicitly intended only for the purpose of understanding the concept of the invention and should not be understood as being limited to the specifically listed embodiments and conditions.

The aforementioned objectives, features, and advantages will become more apparent through the following detailed description in connection with the accompanying drawings, thereby enabling a person skilled in the art to easily implement the technical idea of the invention.

The embodiments described in this specification will be explained with reference to ideal schematic cross-sectional views and/or perspective views of the invention. The thicknesses of the films and regions shown in these drawings are exaggerated for effective explanation of the technical content. The shapes in the exemplary drawings may be modified due to manufacturing techniques and/or tolerances. Additionally, the number of molded objects shown in the drawings is illustrative, and only a portion is shown in the drawings. Therefore, the embodiments of the present invention are not limited to the specific forms shown but also include variations in shape generated according to the manufacturing process.

### Capacitor Component 100 According to the First Embodiment

First, a capacitor component 100 according to a preferred first embodiment of the present invention will be described.

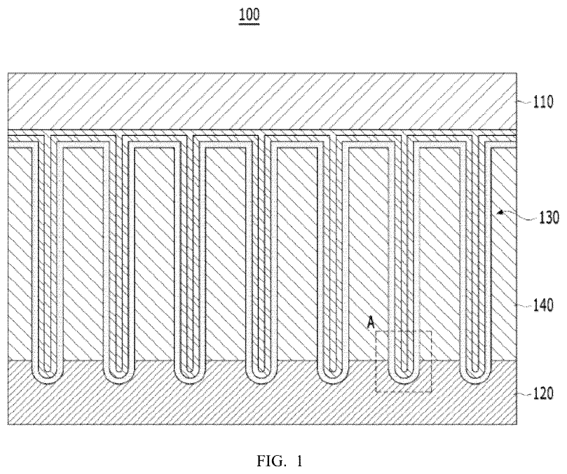

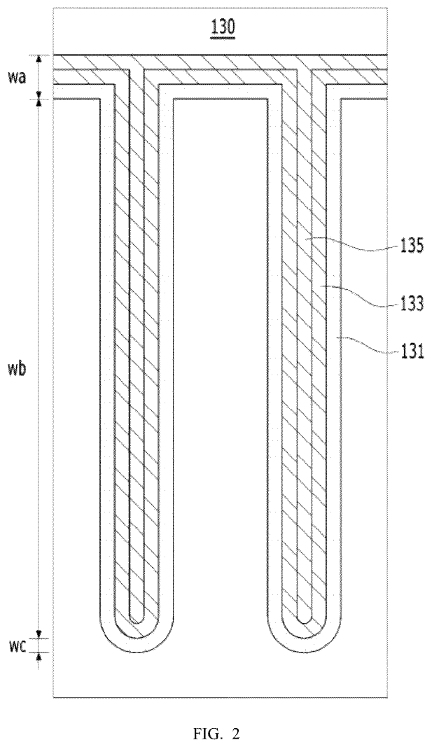

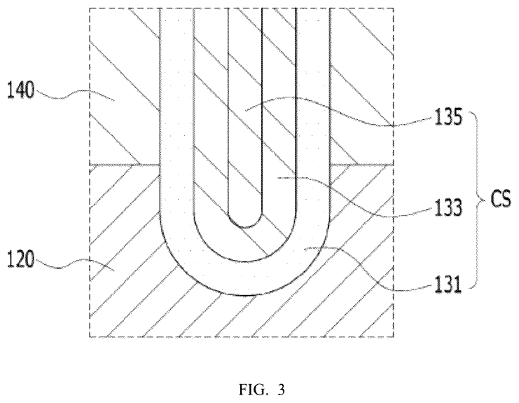

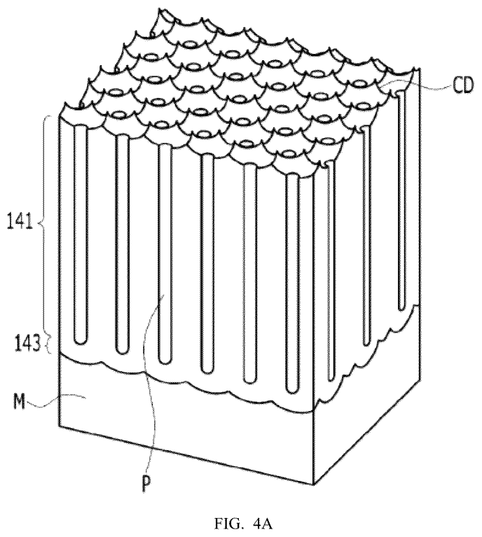

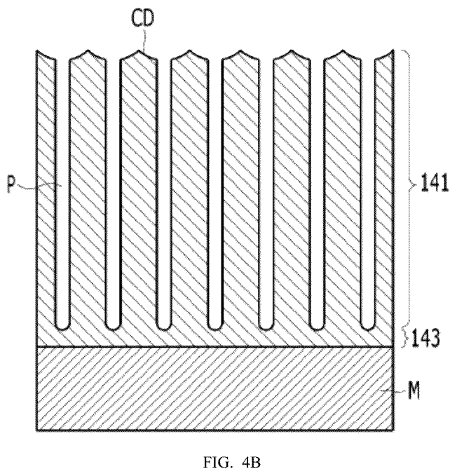

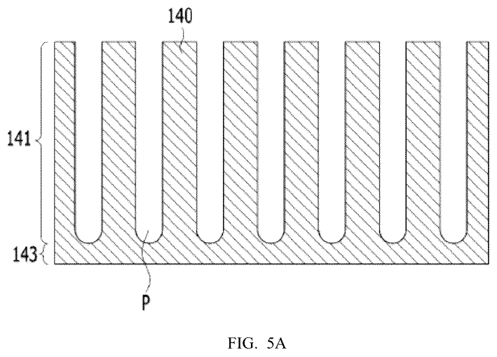

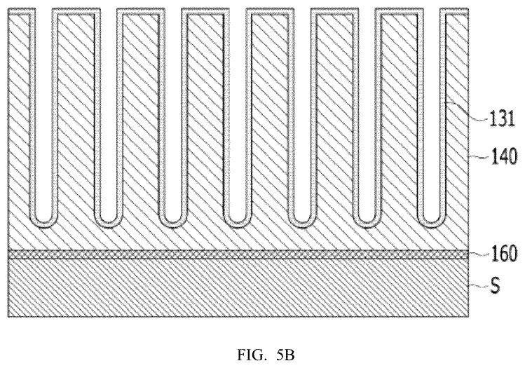

FIG. 1 is a cross-sectional view of a capacitor component 100 according to a preferred first embodiment of the present invention, FIG. 2 is a cross-sectional view of a capacitor wire 130 according to a preferred first embodiment of the present invention, FIG. 3 is an enlarged view of portion A of FIG. 1, and FIGS. 4A to 9B are diagrams for explaining a manufacturing method of the capacitor component 100 according to a preferred first embodiment of the present invention.

Referring to FIGS. 1 to 3, the capacitor component 100 comprises an upper common electrode layer 110, a lower common electrode layer 120, an anodized membrane body 140 provided between the upper common electrode layer 110 and the lower common electrode layer 120 and having a plurality of pores P, and a capacitor wire 130 including a capacitor structure cs formed inside the pores P, wherein an end of the capacitor wire 130 is connected to the lower common electrode layer 120.

The upper common electrode layer 110 and the lower common electrode layer 120 are provided to extend in a horizontal direction, and the capacitor wire 130 is provided to extend in a vertical direction between the upper common electrode layer 110 and the lower common electrode layer 120.

The anodized membrane body 140 is provided between the upper common electrode layer 110 and the lower common electrode layer 120. The capacitor wire 130 extends in a vertical direction inside the pores P of the anodized membrane body 140 and is provided spaced apart in a horizontal direction.

An end of the capacitor wire 130 protrudes from the lower portion of the anodized membrane body 140 and is embedded in the lower common electrode layer 120 The capacitor wire 130 comprises a first wire metal layer 131 provided on an inner wall of the pores P, a dielectric layer 133 provided on the first wire metal layer 131, and a second wire metal layer 135 provided on the dielectric layer 133. The dielectric layer 133 is interposed between the first wire metal layer 131 and the second wire metal layer 135.

The first wire metal layer 131, the dielectric layer 133, and the second wire metal layer 135 are sequentially stacked on the inner wall of the pores P. The first wire metal layer 131 is conformally formed along the inner wall of the pores P. The first wire metal layer is provided in the form of a cylinder with an open top and a closed bottom, and the dielectric layer 133 and the second wire metal layer 135 are provided on the first wire metal layer 131.

The first wire metal layer 131 and the second wire metal layer 135 may each be formed of a metal film consisting of a first metal, a metal oxide film containing the first metal, a metal nitride film containing the first metal, a metal oxynitride film containing the first metal, or a combination thereof. In exemplary embodiments, the first metal may be Ti, Co, Nb, or Sn. In exemplary embodiments, the first wire metal layer 131 and the second wire metal layer 135 may each include Ti, Ti oxide, Ti nitride, Ti oxynitride, Co, Co oxide, Co nitride, Co oxynitride, Nb, Nb oxide, Nb nitride, Nb oxynitride, Sn, Sn oxide, Sn nitride, Sn oxynitride, or a combination thereof. For example, the first wire metal layer 131 and the second wire metal layer 135 may each be formed of TiN, CON, NbN, SnO2, or a combination thereof.

The dielectric layer 133 may be formed of a metal oxide film containing a second metal. The second metal may be Hf, Zr, Nb, Ce, or Ti. In exemplary embodiments, the dielectric layer 133 may be formed of Al₂O₃, ZrO₂, HfO₂, Nb₂O₅, CeO₂, or TiO₂. For example, the first wire metal layer 131 and the second wire metal layer 135 may be formed of TiN films, and the dielectric layer 133 may be formed of a multilayer film in which Al₂O₃ films and ZrO₂ films are alternately stacked multiple times.

The capacitor wire 130 comprises a surface portion wa provided on the surface of the anodized membrane body 140, a column portion wb provided on the inner wall of the pores P, and a bottom portion wc continuously formed with the column portion wb and protruding from the lower portion of the anodized membrane body 140 to be embedded in the lower common electrode layer 120. Here, the bottom portion wc refers to the rounded end of the capacitor wire 130.

Adjacent capacitor wires 130 are connected while sharing the surface portion wa. The portion embedded in the lower common electrode layer 120 may include at least a part of the column portion wb, including the bottom portion wc. The portion of the capacitor wire 130 located inside the pores P is the column portion wb, and the surface portion wa and the bottom portion we are located outside the pores P.

The capacitor wire 130 has a length of 1 μm to 200 μm and a diameter of 10 nm to 1 μm. The capacitor wire 130 is configured in a wire form due to its long length compared to its small diameter. The pitch between adjacent capacitor wires 130 is 20 nm to 200 nm. Thus, the capacitor component 100 includes a plurality of capacitor wires 130 densely arranged with a fine pitch, significantly improving capacitance per unit volume.

The capacitor wire 130 is continuously formed with the surface portion wa, the column portion wb, and the bottom portion wc. The surface portion wa is provided on the surface of the anodized membrane body 140 in the form of a horizontally extending surface, the column portion wb protrudes vertically from the surface portion wa and is provided on the inner wall of the pores P in the form of a column, and the bottom portion wc protrudes from the anodized membrane body 140 and is embedded in the lower common electrode layer 120, anchoring the capacitor wire 130 to the lower common electrode layer 120.

Referring to FIG. 3, an end of the capacitor wire 130 is embedded in and connected to the lower common electrode layer 120. The bottom portion wc of the capacitor wire 130 is formed in a hemispherical shape. Since the bottom portion we is embedded in the lower common electrode layer 120, it fully participates in the current flow through the lower common electrode layer 120. Each capacitor wire 130 is connected to the lower common electrode layer 120. Therefore, in a high-frequency environment, rapid electrical connection with each capacitor wire 130 through the lower common electrode layer 120 is possible.

The capacitor component 100 according to the first embodiment of the present invention may have a thickness of 10 μm to 200 μm in the vertical direction. The capacitor component 100 significantly improves capacitance per unit volume by forming a capacitor structure cs in the pores P of the anodized membrane body 140. For example, particularly because the pores P are densely arranged in a relatively small area, capacitance per unit area is also significantly improved. For example, in the decoupling capacitor 100, the capacitance per 1 mm² may be at least 1000 nF.

Hereinafter, with reference to FIGS. 4A to 9B, a manufacturing method of the capacitor component 100 according to a preferred first embodiment of the present invention will be described. In the following description of the manufacturing method, the configuration of the capacitor component 100 according to the first embodiment may become clearer.

A method of manufacturing a capacitor component 100 according to the first embodiment comprises (i) preparing an anodized membrane body 140, (ii) forming a capacitor wire 130 by filling a capacitor structure cs in pores P of the anodized membrane body 140, (iii) forming an upper common electrode layer 110, and (iv) forming a lower common electrode layer 120.

First, the step of (i) preparing an anodized membrane body 140 is performed.

FIG. 4A is a perspective cross-sectional view after anodizing a base metal M, and FIG. 4B is a cross-sectional view after anodizing the base metal M.

The anodized membrane body 140 refers to a membrane formed by anodizing the base metal M, and the pores P refer to holes formed during the process of forming the anodized membrane by anodizing the base metal M. For example, when the base metal M is aluminum Al or an aluminum alloy, anodizing the base metal M forms an anodized membrane made of aluminum oxide Al₂O₃ on the surface of the base metal M. However, the base metal M is not limited thereto and may include Ta, Nb, Ti, Zr, Hf, Zn, W, Sb, or alloys thereof. The anodized membrane formed as described above is divided into a barrier layer 143, in which pores P are not formed vertically inside, and a porous layer 141, in which pores P are formed inside. A crown protrusion CD is formed on the upper portion of the porous layer 141. The upper surface of each pore P has a concave groove shape, and the concave grooves overlap with adjacent concave grooves to form the crown protrusion CD. Since the crown protrusion CD includes sharp portions, it may become a structurally weak part when depositing the capacitor structure CS by atomic layer deposition ALD.

Referring to FIG. 5A, an anodized membrane body 140 from which the base metal M has been removed is prepared.

After anodizing, when the base metal M is removed, only the anodized membrane body 140 made of aluminum oxide Al₂O₃ remains. The anodized membrane body 140 includes a barrier layer 143 and a porous layer 141. The anodized membrane body 140 may be formed in a structure in which the barrier layer 143 formed during anodizing remains intact, sealing one end of the pores P at the top or bottom. The pores P have a length of 1 μm to 200 μm and a diameter of 10 nm to 1 μm. The pitch between adjacent pores P is 20 nm to 200 nm.

In the present invention, since the pores P of the anodized membrane body 140 are used, a separate process for forming through-holes is unnecessary. Furthermore, by using the pores P of the anodized membrane body 140 to form the capacitor wire 130, high capacitance per unit area can be achieved.

The anodized membrane has a thermal expansion coefficient of 2-3 ppm/°C. As a result, even in high-temperature environments, thermal deformation due to temperature is minimal. Therefore, even if there is a temperature rise to high temperatures in a high-frequency environment, it does not cause a change in the capacitance of the capacitor.

Next, the step of (ii) forming a capacitor wire 130 by filling a capacitor structure cs in the pores P of the anodized membrane body 140 is performed.

Here, the capacitor structure cs comprises a first wire metal layer 131, a dielectric layer 133, and a second wire metal layer 135.

Referring to FIG. 5B, the anodized membrane body 140 is attached to a substrate S using a bonding layer 160. The substrate S may be made of semiconductor or glass. In exemplary embodiments, the substrate S may be made of Si.

Subsequently, a first wire metal layer 131 is formed on the anodized membrane body 140. The first wire metal layer 131 may be formed through a deposition process CVD, PVD, ALD. Preferably, the first wire metal layer 131 is deposited using atomic layer deposition ALD. The pores P are configured in a well shape with an open top and a sealed bottom, and the first wire metal layer 131 is conformally coated along the inner walls of the pores P. The first wire metal layer 131 may be formed with a thickness of 1 nm to 100 nm.

Since the first wire metal layer 131 is formed along the rounded inner walls of the pores P, the charge distribution in the first wire metal layer 131 becomes uniform overall. Unlike the preferred embodiment of the present invention, in a comparative example where a through-hole is formed by etching an insulating film and a capacitor structure is formed on the inner wall of the through-hole, the metal layer is formed in an angular shape at the end, which may cause charge distribution non-uniformity at the angular portions of the end.

The first wire metal layer 131 may be made of a metal film comprising a first metal, a metal oxide film comprising the first metal, a metal nitride film comprising the first metal, a metal oxynitride film comprising the first metal, or a combination thereof. Here, the first metal may be Ti, Co, Nb, or Sn.

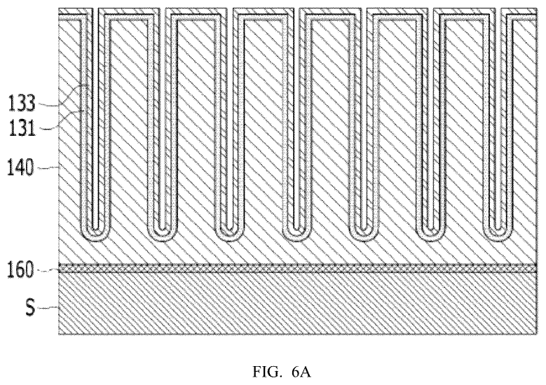

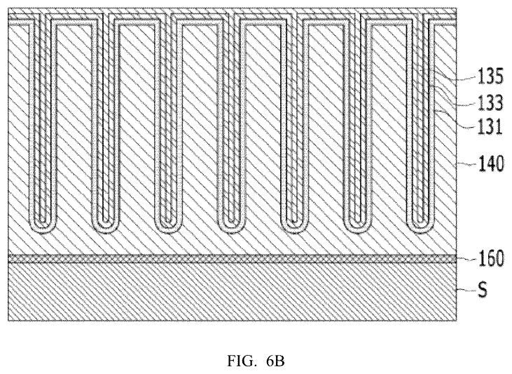

Next, referring to FIG. 6A, a dielectric layer 133 is formed on the first wire metal layer 131. The dielectric layer 133 may be formed through a deposition process CVD, PVD, ALD. Preferably, the dielectric layer 133 is deposited using atomic layer deposition ALD. The pre-deposited first wire metal layer 131 is configured in a well shape with an open top and a sealed bottom, and the dielectric layer 133 is conformally coated along the inner walls of the first wire metal layer 131. The dielectric layer 133 may be formed with a thickness of 1 nm to 100 nm.

The dielectric layer 133 may be made of a metal oxide film comprising a second metal. The second metal may be Hf, Zr, Nb, Ce, or Ti.

Next, referring to FIG. 6B, a second wire metal layer 135 is formed on the dielectric layer 133. The second wire metal layer 135 may be formed through a deposition process CVD, PVD, ALD. Preferably, the second wire metal layer 135 is deposited using atomic layer deposition ALD. The pre-deposited dielectric layer 133 is configured in a well shape with an open top and a sealed bottom, and the second wire metal layer 135 is conformally coated along the inner walls of the dielectric layer 133. The second wire metal layer 135 may be formed with a thickness of 1 nm to 100 nm.

The second wire metal layer 135 may be formed by completely filling the remaining space of the pores P coated with the dielectric layer 133. Alternatively, contrary to what is shown in the drawing, the second wire metal layer 135 may be coated in a well shape with an open top and a sealed bottom, incompletely filling the pores P.

The second wire metal layer 135 may be made of a metal film comprising a first metal, a metal oxide film comprising the first metal, a metal nitride film comprising the first metal, a metal oxynitride film comprising the first metal, or a combination thereof. Here, the first metal may be Ti, Co, Nb, or Sn.

As described above, by filling the capacitor structure cs in the pores P, the capacitor wire 130 is formed. Since the capacitor wire 130 is formed with a high density at a narrow pitch, the capacitance per unit volume can be significantly improved.

Next, the step of (iii) forming an upper common electrode layer 110 is performed.

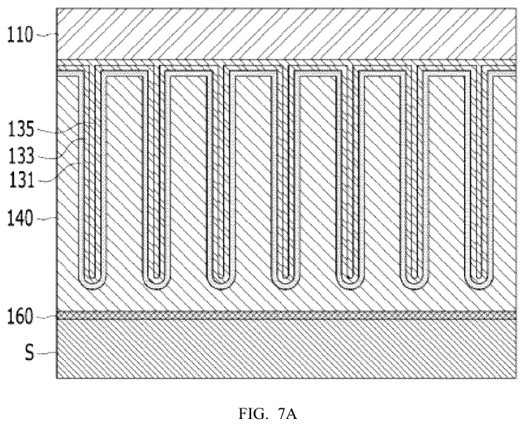

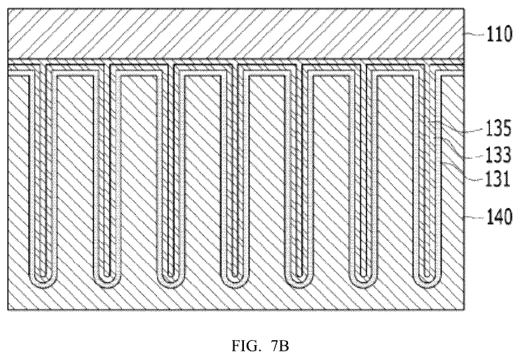

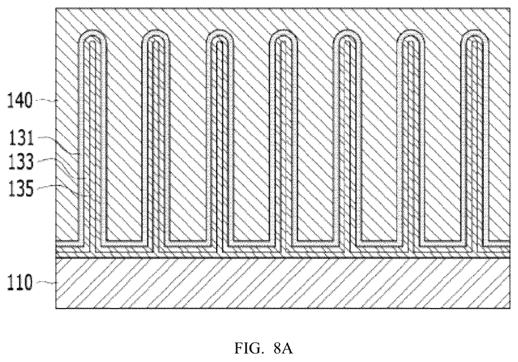

Referring to FIG. 7A, an upper common electrode layer 110 is formed on the upper portion of the second wire metal layer 135. The upper common electrode layer 110 may be made of silver Ag, nickel Ni, copper Cu, tin Sn, indium oxide ITO, palladium Pd, or alloys thereof, but the present invention is not limited thereto. Alternatively, the upper common electrode layer 110 may be formed of the same material as the first wire metal layer and/or the second wire metal layer 135. Alternatively, the upper common electrode layer 110 may be made of a metal film comprising a first metal, a metal oxide film comprising the first metal, a metal nitride film comprising the first metal, a metal oxynitride film comprising the first metal, or a combination thereof. Here, the first metal may be Ti, Co, Nb, or Sn.

Next, as shown in FIG. 7B, the bonding layer 160 and the substrate S are removed.

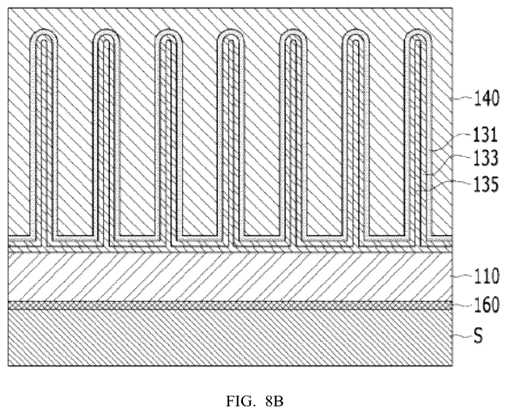

Next, as shown in FIG. 8A, the previously fabricated structure is inverted, and as shown in FIG. 8B, the substrate S is newly attached using the bonding layer 160.

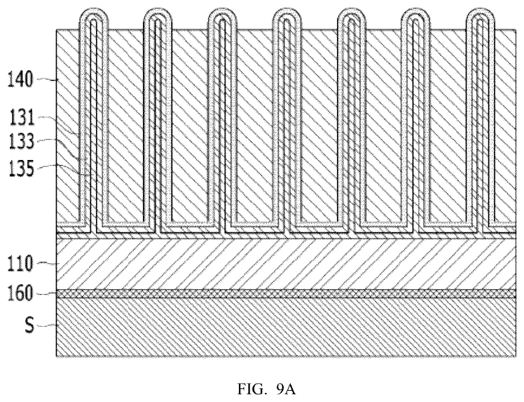

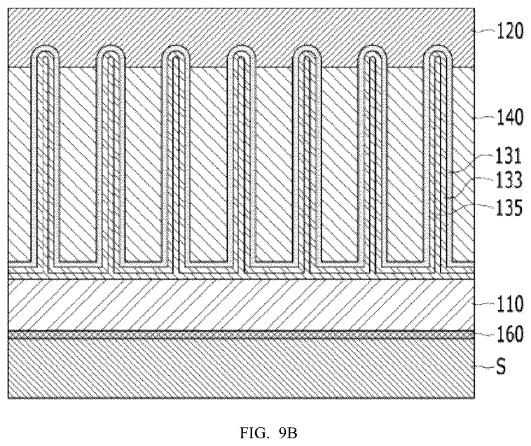

Next, as shown in FIG. 9A, a portion of the anodized membrane body 140 is removed. By wet etching using a solution that reacts only with the anodized membrane, only a portion of the anodized membrane body 140 is removed, exposing the ends of the capacitor wire 130 to protrude from the anodized membrane body 140. More specifically, as a portion of the anodized membrane body 140 is removed by the wet solution, the bottom portion wc of the capacitor wire 130 protrudes from the anodized membrane body 140.

Next, the step of (iv) forming the lower common electrode layer 120 is performed.

As shown in FIG. 9B, the lower common electrode layer 120 is formed in a region where a portion of the anodized membrane body 140 is removed. Accordingly, the bottom portion wc of the capacitor wire 130 is embedded in the lower common electrode layer 120. Here, a portion of the column portion wb of the capacitor wire 130 may also be embedded in the lower common electrode layer 120.

The bottom portion wc of the capacitor wire 130 is embedded in the lower common electrode layer 120 and is not exposed to the outside by the lower common electrode layer 120. Since the lower common electrode layer 120 is formed to cover the end of the capacitor wire 130 protruding from the anodized membrane body 140, there is also an advantage of improving bonding strength.

The lower common electrode layer 120 may be silver (Ag), nickel (Ni), copper (Cu), tin (Sn), indium oxide (ITO), palladium (Pd), or an alloy thereof, but the present invention is not limited thereto. Alternatively, the lower common electrode layer 120 may be formed of the same material as the first wire metal layer and/or the second wire metal layer 135. Alternatively, the lower common electrode layer 120 may be formed of a metal film consisting of a first metal, a metal oxide film containing the first metal, a metal nitride film containing the first metal, a metal oxynitride film containing the first metal, or a combination thereof. Here, the first metal may be Ti, Co, Nb, or Sn.

Next, when the substrate S and the bonding layer 160 are removed, the capacitor component 100 shown in FIG. 1 is completed.

As described above, the capacitor component 100 according to the first preferred embodiment of the present invention significantly improves capacitance per unit volume by densely arranging the capacitor wires 130 extending vertically between the upper common electrode layer 110 and the lower common electrode layer 120, both extending horizontally, while simultaneously stabilizing the electrical flow in the circuit quickly in a high-frequency environment.

In addition, since the capacitor wire 130 is provided in the pores P of the anodized membrane body 140, it exhibits its inherent characteristics without changes in characteristics even in a high-temperature environment.

Furthermore, since the end of the capacitor wire 130 is embedded in the lower common electrode layer 120, the bonding strength with the lower common electrode layer 120 is improved, and it becomes easy to dissipate and remove the thermal energy generated in the capacitor wire 130 to the lower common electrode layer 120.

### Capacitor Component 100 According to the Second Embodiment

Next, the second embodiment according to the present invention will be described. However, the embodiments described below will focus on characteristic components compared to the first embodiment, and descriptions of components that are the same as or similar to those of the first embodiment will be omitted.

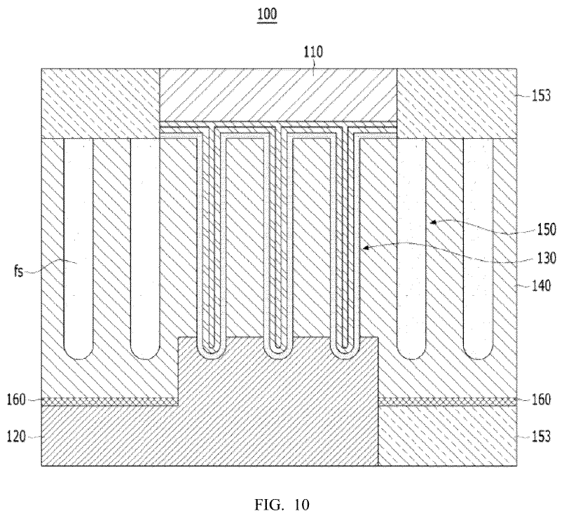

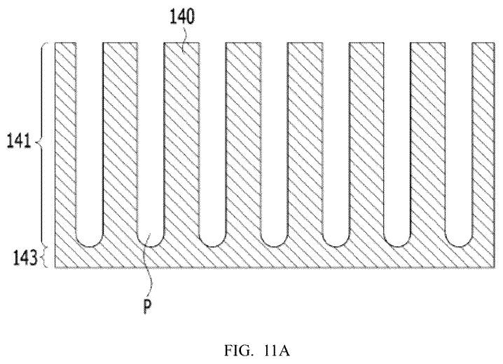

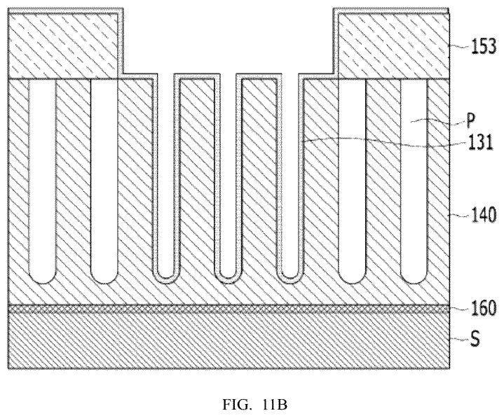

FIG. 10 is a cross-sectional view of the capacitor component 100 according to the second preferred embodiment of the present invention, and FIGS. 11A to 15 are diagrams for explaining the manufacturing method of the capacitor component 100 according to the second preferred embodiment of the present invention.

The capacitor component 100 according to the second embodiment comprises an anodized membrane body 140 provided on the upper portion of the lower common electrode layer 120 and having a plurality of pores P, a capacitor wire 130 including a capacitor structure cs formed in at least some of the pores P, and a functional wire 150 including a functional structure fs formed in at least some of the pores P, wherein an end of the capacitor wire 130 is connected to the lower common electrode layer 120.

The functional wire 150 is formed by filling the functional structure fs inside the pores P. Here, the functional structure fs may be a metal material or an insulating material.

When the functional structure fs is a metal material, it may help dissipate heat from the capacitor wire 130 or perform a function of protecting the capacitor wire 130 from surrounding signal interference.

On the other hand, when the functional structure fs is an insulating material, it may help to enhance the physical properties of the anodized membrane body 140. By filling the insulating material inside the pores P, the overall physical rigidity of the anodized membrane body 140 is improved compared to a structure where the pores P are left as they are.

The functional wire 150 may be located in the peripheral region of the capacitor wire 130. In this case, the functional wire 150 may be positioned on the outer side, and the capacitor wire 130 may be positioned on the inner side. Alternatively, the functional wire 150 may be located between the capacitor wires 130. Alternatively, the functional wire 150 may be positioned in a form surrounded by the capacitor wire 130.

Unlike the capacitor wire 130, a portion of which protrudes from the anodized membrane body 140, the functional wire 150 is not protruded from the anodized membrane body 140 and is provided inside the anodized membrane body 140.

A patternable material 153 is provided at one end of the functional wire 150. The end of the functional wire 150 is closed by the patternable material 153. The patternable material 153 is an insulating material that closes the end of the pores P filled with the functional structure fs, preventing the functional structure fs from leaking to the outside and protecting the functional structure fs from external influences. The patternable material 153 includes a photoresist but is not limited thereto.

Hereinafter, with reference to FIGS. 11A to 15, a manufacturing method of the capacitor component 100 according to the second preferred embodiment of the present invention will be described. Through the description of the manufacturing method below, the configuration of the capacitor component 100 according to the second embodiment may become clearer.

The manufacturing method of the capacitor component 100 according to the second embodiment comprises (i) preparing an anodized membrane body 140, (ii) forming a capacitor wire 130 by filling a capacitor structure cs in the pores P of the anodized membrane body 140, (iii) forming an upper common electrode layer 110, (iv) forming a functional wire 150 by filling a functional structure fs in the pores P of the anodized membrane body 140, and (v) forming a lower common electrode layer 120.

First, the step of (i) preparing the anodized membrane body 140 is performed.

Referring to FIG. 11A, an anodized membrane body 140 from which the base metal M is removed is prepared.

After anodizing, when the base metal M is removed, only the anodized membrane body 140 made of aluminum oxide (Al₂O₃) remains. The anodized membrane body 140 includes a barrier layer 143 and a porous layer 141. The anodized membrane body 140 may be formed in a structure in which the barrier layer 143 formed during anodizing remains as it is, sealing one end of the pores P. The pores have a length of 1 μm to 200 μm and a diameter of 10 nm to 1 μm. The pitch between adjacent pores P is 20 nm to 200 nm.

Next, the step of (ii) forming the capacitor wire 130 by filling the capacitor structure cs in the pores P of the anodized membrane body 140 is performed.

Referring to FIG. 11B, the anodized membrane body 140 is attached to the substrate S using the bonding layer 160. Thereafter, a patternable material (e.g., photoresist PR) is formed on the upper surface of the anodized membrane body 140, and the patternable material 153 is patterned so that some of the pores P are not covered while others are covered. A first wire metal layer 131 is formed in the region where the patternable material 153 does not cover. The first wire metal layer 131 may be formed through a deposition process (CVD, PVD, ALD). Preferably, the first wire metal layer 131 is deposited using an atomic layer deposition (ALD) method. The pores P are configured in a well form with the upper portion open and the lower portion sealed, and the first wire metal layer 131 is conformally coated along the inner wall of the pores P.

The first wire metal layer 131 may be formed of a metal film consisting of a first metal, a metal oxide film containing the first metal, a metal nitride film containing the first metal, a metal oxynitride film containing the first metal, or a combination thereof. Here, the first metal may be Ti, Co, Nb, or Sn.

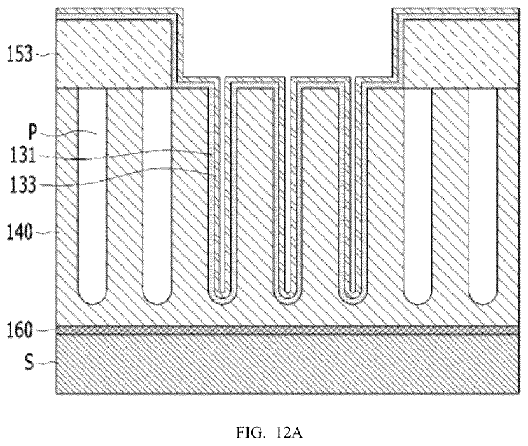

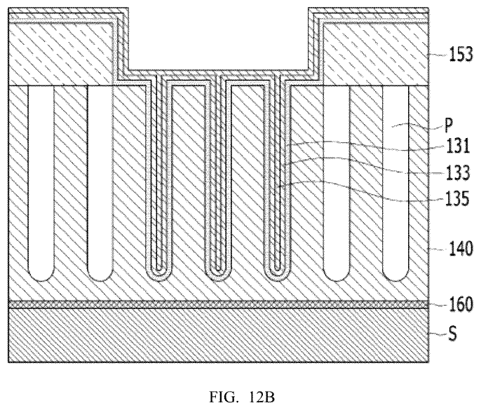

Next, referring to FIG. 12A, a dielectric layer 133 is formed on the first wire metal layer 131. The dielectric layer 133 may be formed through a deposition process (CVD, PVD, ALD). Preferably, the dielectric layer 133 is deposited using an atomic layer deposition (ALD) method. The first wire metal layer 131 is configured in a well form with the upper portion open and the lower portion sealed, and the dielectric layer 133 is conformally coated along the inner wall of the first wire metal layer 131.

The dielectric layer 133 may be formed of a metal oxide film containing a second metal. The second metal may be Hf, Zr, Nb, Ce, or Ti.

Next, referring to FIG. 12B, a second wire metal layer 135 is formed on the dielectric layer 133. The second wire metal layer 135 may be formed through a deposition process (CVD, PVD, ALD). Preferably, the second wire metal layer 135 is deposited using an atomic layer deposition method (ALD). The dielectric layer 133 is configured in a well shape with an open top and a closed bottom, and the second wire metal layer 135 is conformally coated along the inner wall of the dielectric layer 133.

The second wire metal layer 135 may be formed while filling the remaining space of the pores P coated with the dielectric layer 133. Alternatively, contrary to what is shown in the drawing, the second wire metal layer 135 may be coated in a well shape with an open top and a closed bottom, thereby incompletely filling the pores P.

The second wire metal layer 135 may consist of a metal film made of a first metal, a metal oxide film containing the first metal, a metal nitride film containing the first metal, a metal oxynitride film containing the first metal, or a combination thereof. Here, the first metal may be Ti, Co, Nb, or Sn.

As described above, by filling the capacitor structure cs in the pores P, the capacitor wire 130 is formed. Since the capacitor wire 130 is formed with a high density at a narrow pitch interval, the capacitance per unit volume can be significantly improved.

Next, the step of (iii) forming the upper common electrode layer 110 is performed.

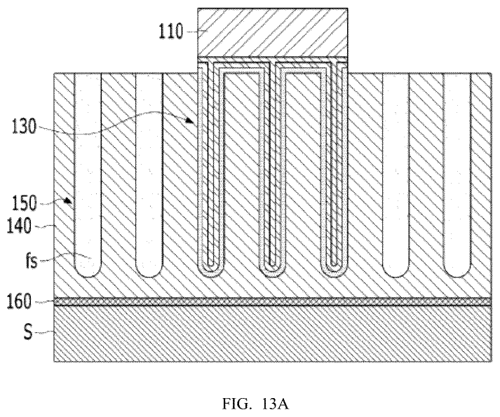

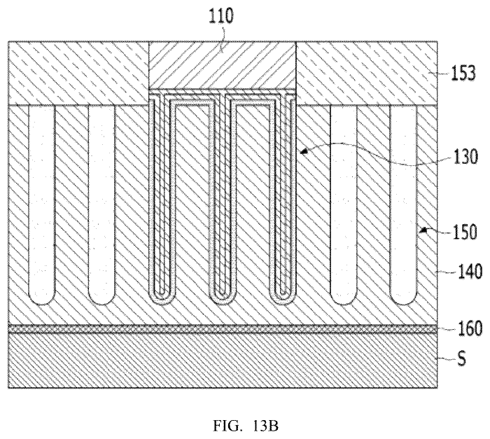

Referring to FIG. 13A, the upper common electrode layer 110 is formed on the upper portion of the second wire metal layer 135. The upper common electrode layer 110 may be silver (Ag), nickel (Ni), copper (Cu), tin (Sn), indium oxide (ITO), palladium (Pd), or an alloy thereof, but the present invention is not limited thereto. Alternatively, the upper common electrode layer 110 may be formed of the same material as the first wire metal layer and/or the second wire metal layer 135. Alternatively, the upper common electrode layer 110 may consist of a metal film made of a first metal, a metal oxide film containing the first metal, a metal nitride film containing the first metal, a metal oxynitride film containing the first metal, or a combination thereof. Here, the first metal may be Ti, Co, Nb, or Sn.

Next, the step of (iv) filling the functional structure fs in the pores P of the anodized membrane body 140 to form the functional wire 150 is performed.

Referring to FIG. 13A, the patternable material 153 on the upper surface of the anodized membrane body 140 may be removed by an appropriate method. The functional structure fs is filled in the pores P of the portion where the patternable material 153 is removed to form the functional wire 150. The functional structure fs may be formed by a deposition method but is not limited thereto. The functional structure fs includes a metal material or an insulating material.

Meanwhile, although it has been described that step of (iii) forming the upper common electrode layer 110 is performed first, followed by step of (iv) filling the functional structure fs in the pores P of the anodized membrane body 140 to form the functional wire 150, the present invention is not limited thereto, and the order may be reversed.

Next, referring to FIG. 13B, the upper portion of the pores P in the area where the functional wire 150 is formed is covered with the patternable material 153. In other words, the patternable material 153 covers the upper portion of the functional wire 150 to protect the functional wire 150 from the outside.

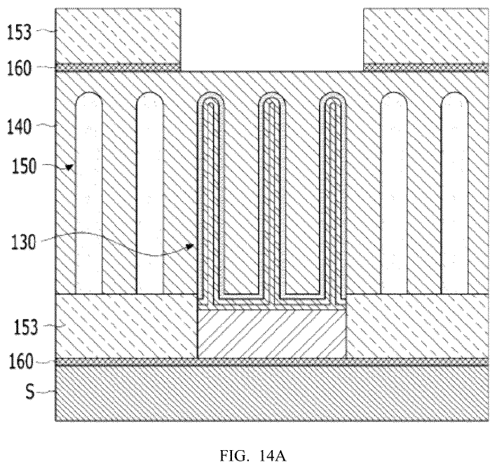

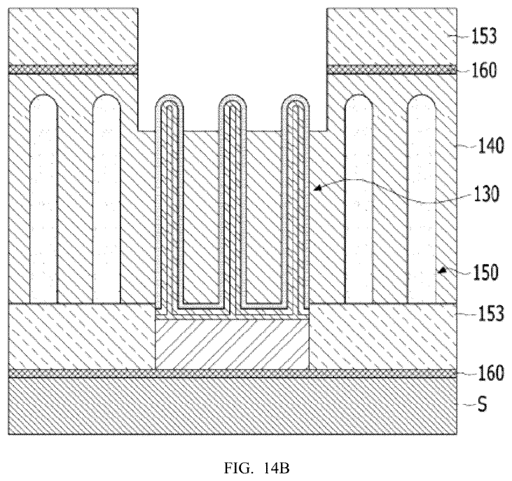

Next, referring to FIG. 14A, the previously manufactured structure is inverted and attached to a new substrate S using a bonding layer 160. Then, the existing substrate S on the upper portion is removed, and the patternable material 153 is patterned at its position.

Next, referring to FIG. 14B, a portion of the anodized membrane body 140 is removed. By wet etching using a solution that reacts only with the anodized membrane, a portion of the anodized membrane body 140 is removed, and the end of the capacitor wire 130 protrudes and is exposed from the anodized membrane body 140. More specifically, as a portion of the anodized membrane body 140 is removed by the wet solution, the bottom portion wc of the capacitor wire 130 protrudes from the anodized membrane body 140.

Next, the step of (iv) forming the lower common electrode layer 120 is performed.

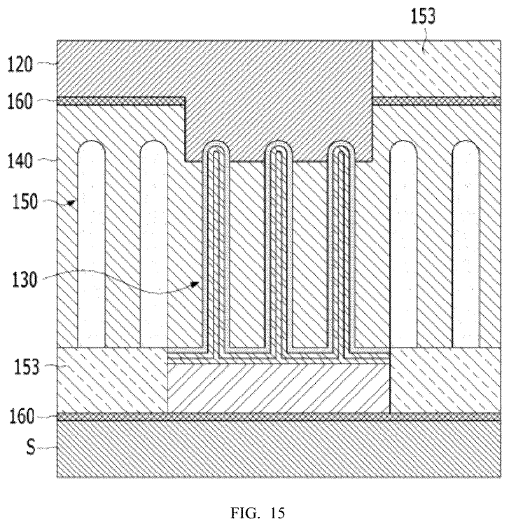

As shown in FIG. 15, the lower common electrode layer 120 is formed in the area where a portion of the anodized membrane body 140 has been removed. Accordingly, the bottom portion wc of the capacitor wire 130 is embedded in the lower common electrode layer 120. The bottom portion wc of the capacitor wire 130 is embedded in the lower common electrode layer 120 and is not exposed to the outside by the lower common electrode layer 120. Since the lower common electrode layer 120 is formed while covering the end of the capacitor wire 130 protruding from the anodized membrane body 140, the bonding strength is also improved.

The lower common electrode layer 120 may be silver (Ag), nickel (Ni), copper (Cu), tin (Sn), indium oxide (ITO), palladium (Pd), or an alloy thereof, but the present invention is not limited thereto. Alternatively, the lower common electrode layer 120 may be formed of the same material as the first wire metal layer and/or the second wire metal layer 135. Alternatively, the lower common electrode layer 120 may consist of a metal film made of a first metal, a metal oxide film containing the first metal, a metal nitride film containing the first metal, a metal oxynitride film containing the first metal, or a combination thereof. Here, the first metal may be Ti, Co, Nb, or Sn.

Next, when the substrate S and the bonding layer 160 are removed, the capacitor component 100 shown in FIG. 10 is completed.

### Capacitor Component 100 According to the Third Embodiment

Next, the third embodiment according to the present invention will be described. However, the embodiments described below will focus on the characteristic components compared to the first embodiment, and descriptions of components that are the same as or similar to those in the first embodiment will be omitted.

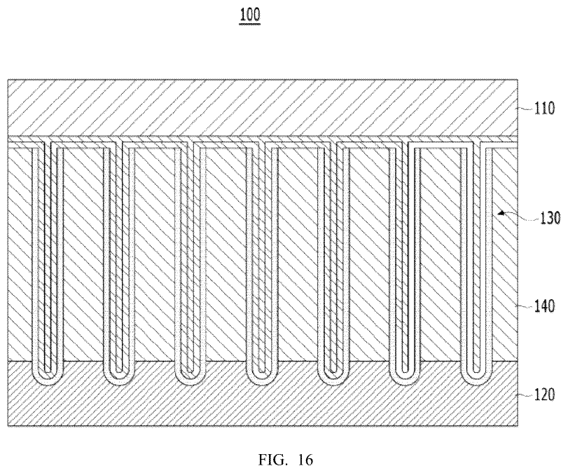

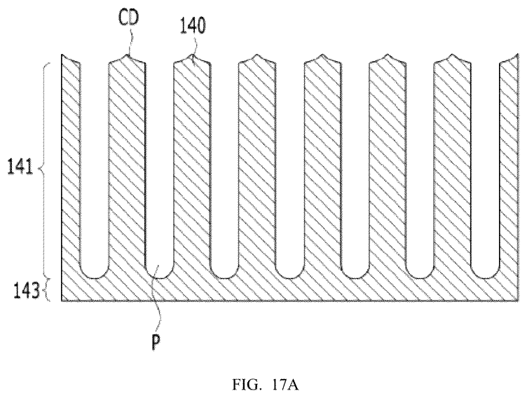

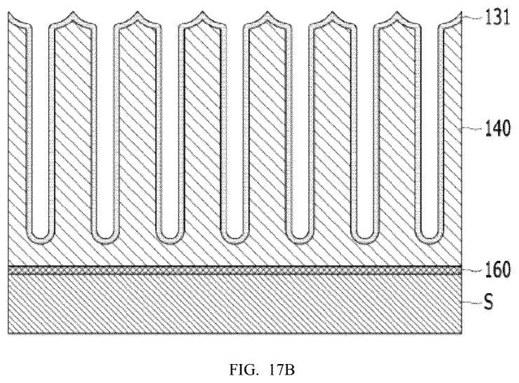

FIG. 16 is a cross-sectional view of a capacitor component 100 according to a preferred third embodiment of the present invention, and FIGS. 17A to 21 are diagrams for explaining a method of manufacturing the capacitor component 100 according to a preferred third embodiment of the present invention.

The capacitor component 100 according to the third embodiment differs from the capacitor component 100 according to the first embodiment in that the first wire metal layer 131 is not formed on the surface of the anodized membrane body 140 but is formed only inside the pores P, while the remaining configuration is the same.

In the third embodiment, the first wire metal layer 131 is not formed on the surface portion wa of the capacitor wire 130 but is formed only on the column portion wb and the bottom portion wc of the capacitor wire 130. This differs from the configuration according to the first embodiment, in which the first wire metal layer 131 is formed on the surface portion wa, the column portion wb, and the bottom portion wc of the capacitor wire 130.

Hereinafter, referring to FIGS. 17A to 21, a method of manufacturing the capacitor component 100 according to a preferred third embodiment of the present invention will be described. Through the description of the manufacturing method below, the configuration of the capacitor component 100 according to the third embodiment can become clearer.

The method of manufacturing the capacitor component 100 according to the third embodiment comprises step of (i) preparing the anodized membrane body 140, step of (ii) filling the capacitor structure cs in the pores P of the anodized membrane body 140 to form the capacitor wire 130, step of (iii) forming the upper common electrode layer 110, and step of (iv) forming the lower common electrode layer 120.

First, the step of (i) preparing the anodized membrane body 140 is performed.

Referring to FIG. 17A, the anodized membrane body 140 from which the base metal M has been removed is prepared.

After anodization, when the base metal M is removed, only the anodized membrane body 140 made of aluminum oxide (Al₂O₃) remains. The anodized membrane body 140 includes a barrier layer 143 and a porous layer 141. The anodized membrane body 140 may be formed in a structure in which the barrier layer 143 formed during anodization remains as it is, sealing one end of the pores P at the top or bottom.

Crown protrusions CD are formed on the upper portion of the porous layer 141. The upper surface of each pore P has a concave groove shape, and the concave grooves overlap with adjacent concave grooves to form the crown protrusions CD.

Next, the step of (ii) filling the capacitor structure cs in the pores P of the anodized membrane body 140 to form the capacitor wire 130 is performed.

Referring to FIG. 17B, the anodized membrane body 140 is attached to the substrate S using the bonding layer 160. Subsequently, the first wire metal layer 131 is formed on the upper surface of the anodized membrane body 140. The first wire metal layer 131 may be formed through a deposition process (CVD, PVD, ALD). Preferably, the first wire metal layer 131 is deposited using an atomic layer deposition (ALD) method. The pores P are configured in a well form with an open top and a closed bottom, and the first wire metal layer 131 is conformally coated along the inner wall of the pores P. The first wire metal layer 131 is uniformly coated over the surface of the crown protrusion CD as well.

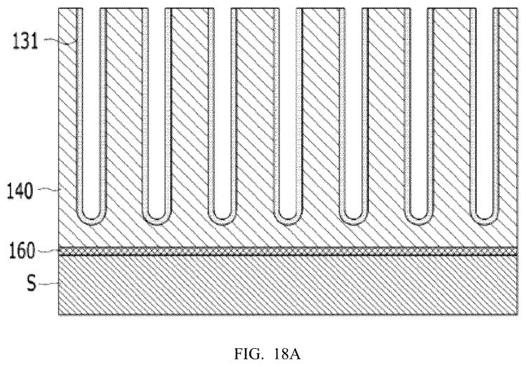

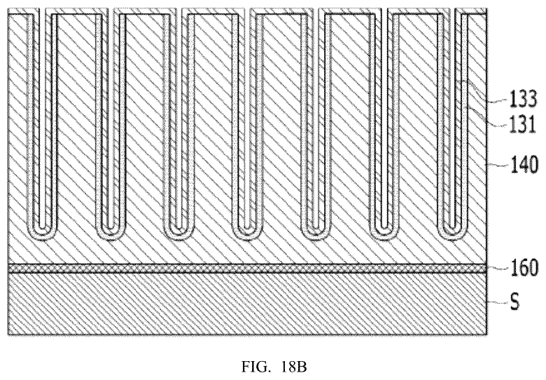

Next, referring to FIG. 18A, the upper surface of the anodized membrane body 140 is planarized. The planarization is performed by removing the crown protrusion CD through a chemical mechanical polishing (CMP) process. As the crown protrusion CD portion is removed, the first wire metal layer 131 is absent on the surface of the anodized membrane body 140, and the first wire metal layer 131 is provided only inside the pores P.

The first wire metal layer 131 may consist of a metal film made of a first metal, a metal oxide film containing the first metal, a metal nitride film containing the first metal, a metal oxynitride film containing the first metal, or a combination thereof. Here, the first metal may be Ti, Co, Nb, or Sn.

Next, referring to FIG. 18B, a dielectric layer 133 is formed on the first wire metal layer 131. The dielectric layer 133 may be formed through a deposition process (CVD, PVD, ALD). Preferably, the dielectric layer 133 is deposited using an atomic layer deposition (ALD) method. The first wire metal layer 131 is configured in a well form with an open top and a closed bottom, and the dielectric layer 133 is conformally coated along the inner wall of the first wire metal layer 131. The dielectric layer 133 is also formed on the surface of the anodized membrane body 140.

The dielectric layer 133 may consist of a metal oxide film containing a second metal. The second metal may be Hf, Zr, Nb, Ce, or Ti.

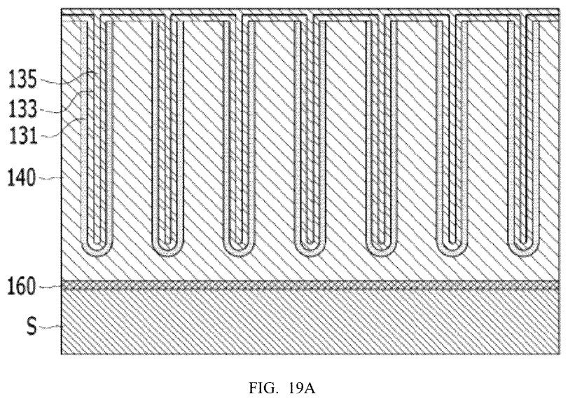

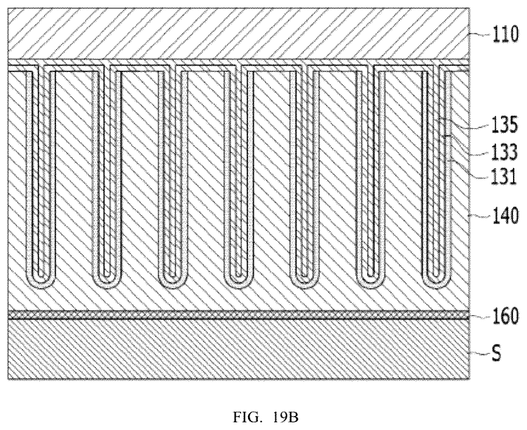

Next, referring to FIG. 19A, a second wire metal layer 135 is formed on the dielectric layer 133. The second wire metal layer 135 may be formed through a deposition process (CVD, PVD, ALD). Preferably, the second wire metal layer 135 is deposited using an atomic layer deposition (ALD) method. The dielectric layer 133 is configured in a well form with an open top and a closed bottom, and the second wire metal layer 135 is conformally coated along the inner wall of the dielectric layer 133.

The second wire metal layer 135 may be formed while filling the remaining space of the pores P coated with the dielectric layer 133. Alternatively, Contrary to what is shown in the drawing, the second wire metal layer 135 may be coated in a well form with an open top and a closed bottom, incompletely filling the pores P.

The second wire metal layer 135 may consist of a metal film made of the first metal, a metal oxide film containing the first metal, a metal nitride film containing the first metal, a metal oxynitride film containing the first metal, or a combination thereof. Here, the first metal may be Ti, Co, Nb, or Sn.

As described above, by filling the capacitor structure cs inside the pores P, the capacitor wire 130 is formed. Since the capacitor wire 130 is formed with a high density at a narrow pitch interval, the capacitance per unit volume can be significantly improved.

Next, the step of (iii) forming the upper common electrode layer 110 is performed.

Referring to FIG. 19B, the upper common electrode layer 110 is formed on the upper portion of the second wire metal layer 135. The upper common electrode layer 110 may be silver (Ag), nickel (Ni), copper (Cu), tin (Sn), indium oxide (ITO), palladium (Pd), or an alloy thereof, but the present invention is not limited thereto. Alternatively, the upper common electrode layer 110 may be formed of the same material as the first wire metal layer and/or the second wire metal layer 135. Alternatively, the upper common electrode layer 110 may consist of a metal film made of the first metal, a metal oxide film containing the first metal, a metal nitride film containing the first metal, a metal oxynitride film containing the first metal, or a combination thereof. Here, the first metal may be Ti, Co, Nb, or Sn.

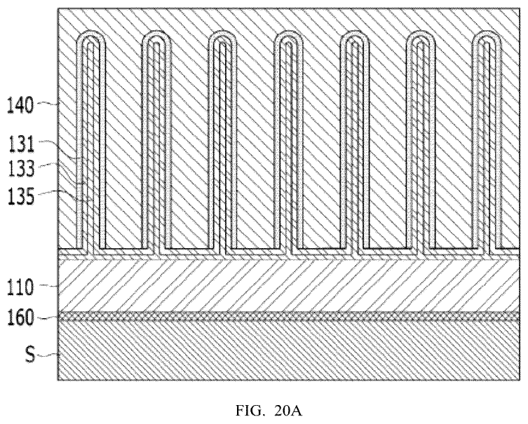

Next, as shown in FIG. 20A, the bonding layer 160 and the substrate S are removed. Then, the previously fabricated structure is inverted, and the substrate S is attached using the bonding layer 160.

Next, as shown in FIG. 20B, a portion of the anodized membrane body 140 is removed. By wet etching using a solution that reacts only with the anodized membrane, only a portion of the anodized membrane body 140 is removed, exposing the ends of the capacitor wire 130 protruding from the anodized membrane body 140. More specifically, as a portion of the anodized membrane body 140 is removed by the wet solution, the bottom portion wc of the capacitor wire 130 protrudes from the anodized membrane body 140.

Next, the step of (iv) forming the lower common electrode layer 120 is performed.

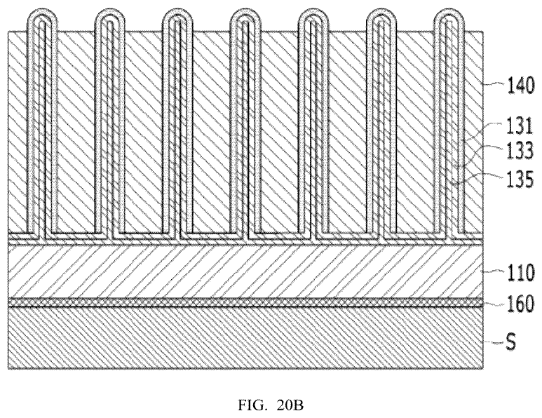

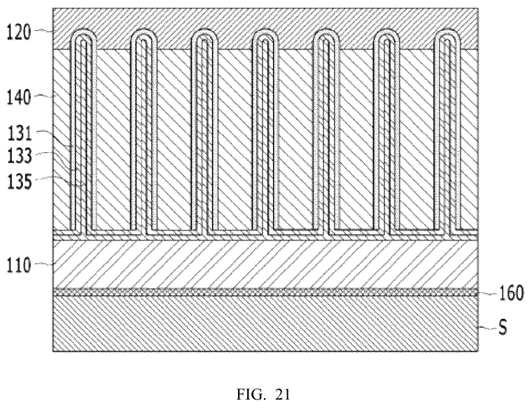

As shown in FIG. 21, the lower common electrode layer 120 is formed in the region where a portion of the anodized membrane body 140 has been removed. Accordingly, the bottom portion wc of the capacitor wire 130 is embedded in the lower common electrode layer 120. The bottom portion wc of the capacitor wire 130 is embedded in the lower common electrode layer 120 and is not exposed to the outside by the lower common electrode layer 120. Since the lower common electrode layer 120 is formed to cover the ends of the capacitor wire 130 protruding from the anodized membrane body 140, the bonding strength is also improved.

The lower common electrode layer 120 may be silver (Ag), nickel (Ni), copper (Cu), tin (Sn), indium oxide (ITO), palladium (Pd), or an alloy thereof, but the present invention is not limited thereto. Alternatively, the lower common electrode layer 120 may be formed of the same material as the first wire metal layer and/or the second wire metal layer 135. Alternatively, the lower common electrode layer 120 may consist of a metal film made of the first metal, a metal oxide film containing the first metal, a metal nitride film containing the first metal, a metal oxynitride film containing the first metal, or a combination thereof. Here, the first metal may be Ti, Co, Nb, or Sn.

Next, by removing the substrate S and the bonding layer 160, the capacitor component 100 shown in FIG. 16 is completed.

### Integrated Circuit Chip Package 1000

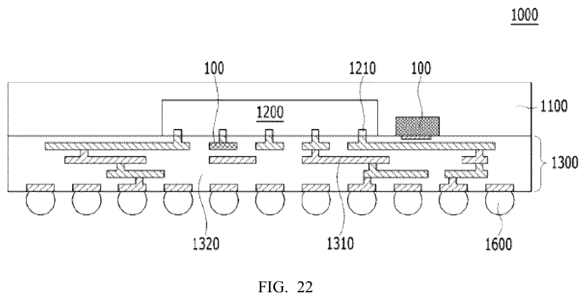

FIG. 22 is a cross-sectional view of an integrated circuit chip package 1000 including the capacitor component 100 according to a preferred embodiment of the present invention.

The integrated circuit chip package 1000 according to a preferred embodiment of the present invention includes a package substrate 1300, a semiconductor chip 1200 mounted on the package substrate 1300, a molding portion 1100 protecting the semiconductor chip 1200, and a capacitor component 100 provided inside or on the package substrate 1300.

The semiconductor chip 1200 may be a logic chip including a logic circuit. The logic chip may be a controller for controlling memory chips. In other exemplary embodiments, the semiconductor chip 1200 may be a memory chip. The memory chip may include various types of memory circuits. The memory circuit may consist of DRAM (Dynamic Random Access Memory), SRAM (Static RAM), FRAM (Ferromagnetic RAM), PRAM (Phase Change RAM), MRAM (Magnetic RAM), RRAM (Resistive RAM), ROM (Read Only Memory), MROM (Mask ROM), PROM (Programmable ROM), EPROM (Erasable ROM), EEPROM (Electrically Erasable ROM), or a combination thereof.

The package substrate 1300 may include a plurality of wiring layers 1310 configured to be electrically connected to a plurality of chip pads 1210 included in the semiconductor chip 1200, and an insulating film 1320 for selectively insulating adjacent wiring layers 1310 among the plurality of wiring layers 1310. The plurality of wiring layers 1310 included in the package substrate 1300 may include Al, Cu, Sn, Ni, Au, Pt, or an alloy thereof. A plurality of external connection members 1600 may be connected to the package substrate 1300.

The package substrate 1300 includes the capacitor component 100. The capacitor component 100 may be configured to be electrically connectable to some of the chip pads 1210 included in the semiconductor chip 1200, or to some of the wiring layers 1310 selected from the plurality of wiring layers 1310 included in the package substrate 1300. The capacitor component 100 may include any one selected from the capacitor components 100 according to the first to third embodiments.

According to the trend of high integration and high speed of the semiconductor chip 1200, noise generated at the ground plane and the power terminal due to high-speed switching in the internal and external wiring of the integrated circuit chip package 1000 may cause malfunction of the semiconductor chip 1200. However, the capacitor component 100 according to the present invention minimizes the impact of such noise. The integrated circuit chip package 1000 comprising the capacitor component 100 according to the present invention, based on the advantages of the capacitor component 100, exhibits superior performance in high-frequency environments compared to conventional MLCCs and can be advantageously applied to small IT devices such as smartwatches, HPC, and the 5G field of high-frequency bands.

As described above, although the preferred embodiments of the present invention have been described with reference to the foregoing, those skilled in the art can implement the present invention in various modifications or alterations without departing from the spirit and scope of the present invention as set forth in the following claims.

### DESCRIPTION OF THE REFERENCE NUMERALS IN THE DRAWINGS

100: Capacitor component
110: Upper common electrode layer
120: Lower common electrode layer
130: Capacitor wire
140: Anodized membrane body
150: Functional wire

1. A capacitor component comprising:
an anodized membrane body having a plurality of pores;
a first wire metal layer provided on an inner wall of the pores;
a dielectric layer provided on the first wire metal layer;
a second wire metal layer provided on the dielectric layer; and
a lower common electrode layer connected to the first wire metal layer at a lower portion of the anodized membrane body.

2. The capacitor component according to claim 1, wherein
an end of the first wire metal layer protrudes from the lower portion of the anodized membrane body and is embedded in the lower common electrode layer.

3. A capacitor component comprising:
a lower common electrode layer;
an anodized membrane body provided on an upper portion of the lower common electrode layer and having a plurality of pores; and
a capacitor wire including a capacitor structure formed inside the pores,
wherein an end of the capacitor wire is connected to the lower common electrode layer.

4. The capacitor component according to claim 3, wherein
the capacitor wire comprises:
a first wire metal layer provided on an inner wall of the pores;
a dielectric layer provided on the first wire metal layer; and
a second wire metal layer provided on the dielectric layer.

5. The capacitor component according to claim 3, wherein
an end of the capacitor wire protrudes from a lower portion of the anodized membrane body and is embedded in the lower common electrode layer.

6. The capacitor component according to claim 3, wherein
the capacitor wire comprises:
a surface portion provided on a surface of the anodized membrane body;
a column portion provided on an inner wall of the pores; and
a bottom portion continuously formed with the column portion and protruding from the lower portion of the anodized membrane body to be embedded in the lower common electrode layer.

7. The capacitor component according to claim 3, wherein
the lower common electrode layer is provided to extend in a horizontal direction, and
the capacitor wire extends in a vertical direction and a plurality thereof are provided spaced apart in the horizontal direction.

8. A capacitor component comprising:
an anodized membrane body provided on an upper portion of the lower common electrode layer and having a plurality of pores;
a capacitor wire including a capacitor structure formed in at least some of the pores; and
a functional wire including a functional structure formed in at least some of the pores,
wherein an end of the capacitor wire is connected to the lower common electrode layer.

9. The capacitor component according to claim 8, wherein
the functional structure is a metal material.

10. The capacitor component according to claim 8, wherein
the functional structure is an insulating material.

11. The capacitor component according to claim 8, wherein
an end of the functional wire is closed by a patternable material.

12. (canceled)

13. (canceled)

14. (canceled)

15. (canceled)
